(19) United States
(12) Patent Application Publication
(10) Pub. No.: US 2026/0031303 A1
(43) Pub. Date: Jan. 29, 2026

(54) DYNAMIC IMPEDANCE CONTROL FOR A SUBSTRATE SUPPORT OF A PLASMA PROCESSING SYSTEM

(71) Applicant: Applied Materials, Inc., Santa Clara, CA (US)

(72) Inventors: Zheng John YE, Santa Clara, CA (US); Hsiang AN, San Jose, CA (US); Jianhua ZHOU, Campbell, CA (US); Jinhyun CHO, Santa Clara, CA (US); Sheng-Yi WANG, Tainan (TW); Hanzheng H. LIN, Santa Clara, CA (US); Suhail ANWAR, Saratoga, CA (US); Fei PENG, San Jose, CA (US); Sang Jeong OH, Sunnyvale, CA (US); Soo Young CHOI, Fremont, CA (US); Lai ZHAO, Campbell, CA (US); Yao-yuan TU, Tainan (TW); Yan-chi PAN, Tainan (TW); Shan YEH, Tainan (TW); Chia-Pin LIN, Tainan (TW)

(21) Appl. No.: 19/281,891

(22) Filed: Jul. 28, 2025

Related U.S. Application Data
(60) Provisional application No. 63/676,500, filed on Jul. 29, 2024.

(51) Int. Cl. H01J 37/32

(52) U.S. Cl. CPC H01J 37/32183; H01J 2237/3323

(57) ABSTRACT

A process kit generally includes a substrate support and a plurality of tuner circuits electrically coupled to the substrate support and an electrical ground. Each of the plurality of tuner circuits may be configured to adjust a ground path from the substrate support to the electrical ground during processing of a substrate supported by the substrate support to dynamically tune an impedance of the substrate support to control uniformity associated with a deposition rate of a film of material deposited onto the substrate.

### CROSS-REFERENCE TO RELATED APPLICATION

This application claims the benefit of U.S. Provisional Application No. 63/676,500, titled “Dynamic Impedance Control for a Substrate Support of a Plasma Processing System” filed 29 Jul. 2024, the contents of which is incorporated herein in its entirety.

### BACKGROUND

### Field

Embodiments described herein generally relate to methods and apparatuses for dynamically controlling the impedance of a substrate support supporting a large substrate to control uniformity of a deposition rate for a thin film deposited onto the large substrate during processing.

### Description of the Related Art

Plasma enhanced chemical vapor deposition (PECVD) is generally employed to deposit thin films on substrates, such as semiconductor substrates, solar panel substrates, and liquid crystal display (LCD) and organic light emitting diode (OLED) substrates used in display manufacture. PECVD is generally accomplished by introducing a precursor gas into a vacuum chamber having a substrate disposed on a substrate support. The precursor gas is typically directed through a gas distribution plate situated near the top of the vacuum chamber. The precursor gas in the vacuum chamber is energized (e.g., excited) into a plasma by applying a radio frequency (RF) power to the chamber from one or more RF sources coupled to the chamber. The excited gas reacts to form a thin film of material on a surface of the substrate (or devices formed thereon). The gas distribution plate is generally connected to a RF power source and the substrate support is typically connected to the chamber body providing a path to ground for RF currents.

In the manufacture of OLED devices, PECVD process are generally used to form a thin film on a plurality of OLED devices formed on a substrate. The thin film is utilized to encapsulate and/or hermetically seal the devices (known as thin film encapsulation (TFE)). Uniformity is generally desired in these thin films deposited on the OLED devices using PECVD processes. When the thickness of the thin films are not uniform across the substrate area, the yield may be decreased. It has been found that the non-uniformity is related to plasma density uniformity, which is affected by the impedance of the substrate support.

Therefore, what is needed are systems and methods for dynamically tuning the impedance of the substrate support to provide improved uniformity of the deposition rate of the thin film deposited on the OLED devices.

### SUMMARY

In one aspect, a process kit is provided. The process kit includes: a substrate support; and a plurality of tuner circuits electrically coupled to the substrate support and an electrical ground, each of the plurality of tuner circuits configured to adjust a ground path from the substrate support to the electrical ground during processing of the substrate to dynamically tune an impedance of the substrate support to control uniformity associated with a deposition rate of a film of material deposited onto a substrate supported by the substrate support.

In another aspect, a plasma processing system is provided. The plasma processing system includes: a processing chamber defining a processing volume; a substrate support disposed within the processing volume; and a plurality of tuner circuits disposed outside the processing volume, the plurality of tuner circuits electrically coupled to the substrate support and an electrical ground, the plurality of tuner circuits including one or more tuner circuits configured to adjust a ground path from the substrate support to the electrical ground during processing of a substrate supported by the substrate support to dynamically tune an impedance of the substrate support to control uniformity associated with a deposition rate of a film of material deposited onto the substrate.

In yet another aspect, a method for configuring a plurality of tuner circuits electrically coupled between an electrical ground and a substrate support supporting a substrate during a process in which a film of material is deposited onto the substrate, the method comprising: obtaining input data comprising one or more parameters for each of the plurality of tuner circuits; providing the input data to a trained machine learning model, the trained machine learning model configured to process the input data and generate output data based on the input data, the output data indicative of a thickness of the film of material at a plurality of different locations on the substrate; and adjusting the one or more parameters for one or more tuner circuits of the plurality of tuner circuits based on the output data.

### BRIEF DESCRIPTION OF THE DRAWINGS

So that the manner in which the above recited features of the disclosure can be understood in detail, a more particular description as described herein, briefly summarized above, may be had by reference to embodiments, some of which are illustrated in the appended drawings. It is to be noted, however, that the appended drawings illustrate only typical embodiments of this disclosure and are therefore not to be considered limiting of scope, for the disclosure may admit to other equally effective embodiments.

FIG. 1 is a schematic, cross-sectional view of a plasma processing system according to some embodiments of the present disclosure.

FIG. 2 is a block diagram of components of a system for dynamically tuning an impedance of a substrate support of a plasma processing system according to some embodiments of the present disclosure.

FIG. 3A is a tuner circuit having an inductor and tunable capacitor arranged in a parallel configuration according to some embodiments of the present disclosure.

FIG. 3B is a tuner circuit having an inductor and tunable capacitor arranged in a series configuration according to some embodiments of the present disclosure.

FIG. 3C is a tuner circuit having a capacitor and a tunable inductor arranged in a parallel configuration according to some embodiments of the present disclosure.

FIG. 3D is a tuner circuit having a capacitor and a tunable inductor arranged in a series configuration according to some embodiments of the present disclosure.

FIG. 3E is tuner circuit selectively coupled to a connection to a substrate support via a switching device according to some embodiments of the present disclosure.

FIG. 3F is a switching device in parallel with a tuner circuit to selectively bypass the tuner circuit according to some embodiments of the present disclosure.

FIG. 4A is a first configuration of tuner circuits electrically coupled to a substrate support of a plasma processing system to dynamically tune the impedance of the substrate support according to some embodiments of the present disclosure.

FIG. 4B is a second configuration of tuner circuits electrically coupled to a substrate support of a plasma processing system to dynamically tune the impedance of the substrate support according to some embodiments of the present disclosure.

FIG. 4C is a third configuration of tuner circuits electrically coupled to a substrate support of a plasma processing system to dynamically tune the impedance of the substrate support according to some embodiments of the present disclosure.

FIG. 5A is a two-dimensional map depicting the thickness of a film deposited onto a substrate supported by a substrate support without a tuner circuit coupled thereto.

FIG. 5B is a two-dimensional map depicting thickness of a film deposited onto a substrate supported by a substrate support whose impedance is dynamically tuned by first and second tuner circuits arranged in a first configuration according to some embodiments of the present disclosure.

FIG. 5C is a two-dimensional map depicting thickness of a film deposited onto a substrate supported by a substrate support whose impedance is dynamically tuned by first and second tuner circuits arranged in a second configuration according to some embodiments of the present disclosure.

FIG. 6A is a plot depicting a resonance point of a tuner circuit for different power curves associated with generating plasma according to some embodiments of the present disclosure.

FIG. 6B is a plot depicting a resonance point of a tuner circuit for different power curves associated with generating plasma according to some embodiments of the present disclosure.

FIG. 6C is a plot depicting a voltage of a tuner circuit as a capacitance of a capacitor thereof is scanned to adjust a deposition rate of a thin film on a substrate according to some embodiments of the present disclosure.

FIG. 7A is a schematic of connection points on a substrate support for connecting tuner circuits to the substrate support according to some embodiments of the present disclosure.

FIG. 7B is a plot illustrating how dynamically tuning the impedance of the substrate support from different connection points thereon changes an electric field profile of a substrate supported by the substrate support according to some embodiments of the present disclosure.

FIG. 8A is a deposition thickness map for a substrate according to some embodiments of the present disclosure.

FIG. 8B is block diagram of a machine learning based approach for configuring a plurality of tuner circuits to dynamically tune the impedance of a substrate support supporting a substrate according to some embodiments of the present disclosure.

FIG. 9 is a flowchart depicting a method for configuring a plurality of tuner circuits electrically coupled between an electrical ground and a substrate support supporting a substrate during a process in which a film of material is deposited onto the substrate according to some embodiments of the present disclosure.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

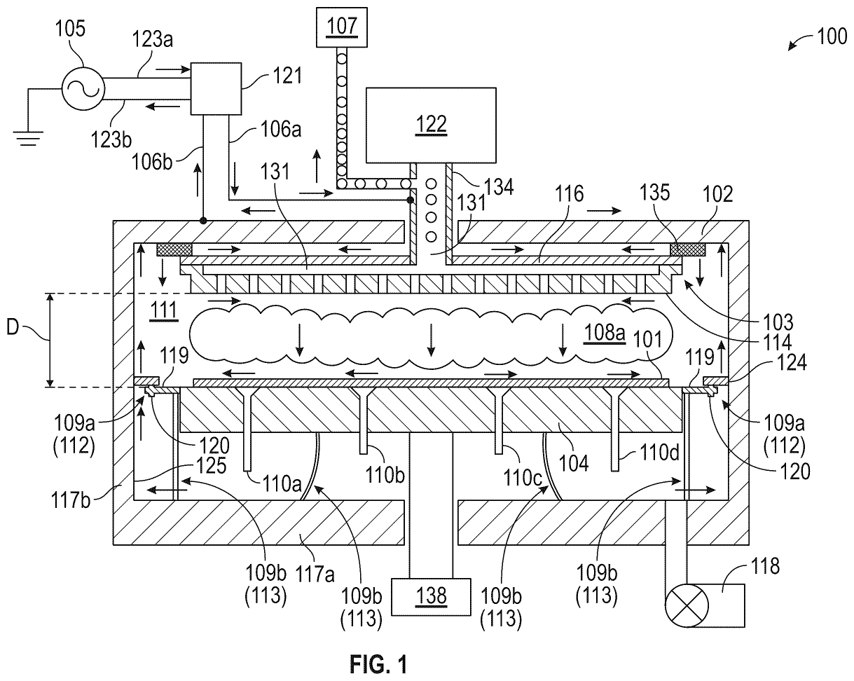

The present disclosure generally relates to processing a large area substrate using plasma. As will be described in FIG. 1 in more detail, a plasma processing system configured to process the large area substrate may include a processing chamber and a substrate support (e.g., disposed within the processing chamber) configured to support the large area substrate. While the substrate support is supporting the large area substrate, a gas may be injected into the processing chamber and may interact with plasma (e.g., generated by applying RF power to a backing plate of the plasma processing system) that is also in the processing chamber. The gas-plasma reaction may cause a thin film of material (e.g., silicon) to be deposited onto the large area substrate.

The substrate support is typically grounded to the processing chamber at multiple locations via one or more grounding straps. The one or more grounding straps provide a path to ground for RF currents associated with the RF power that is applied to generate the plasma. The path to ground is typically fixed and, based on this, the impedance of the substrate support cannot be adjusted during processing of the substrate through adjustments to the one or more grounding straps. This inability to dynamically tune the impedance of the substrate support during processing of the substrate may result in the thin film of material being applied in a non-uniform matter. For example, the thin film of material may be deposited on a first area (e.g., corner) of the substrate at a first deposition rate and the thin film of material may be deposited on a second area (e.g., middle) of the substrate at a second deposition rate that is different (e.g., faster or slower) than the first deposition rate. This inconsistency in the deposition rate of the thin film of material may lead to undesirable variations (e.g., greater than 10 percent) in the thickness of the thin film of material across the substrate.

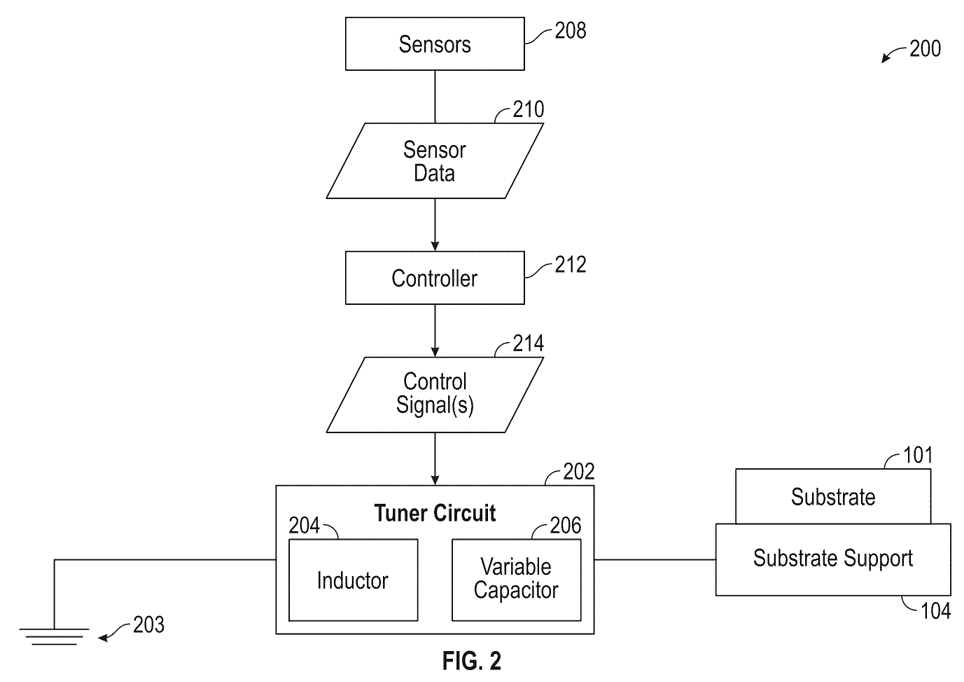

Example aspects of the present disclosure are directed to techniques for dynamically tuning an impedance of the substrate support during processing of the substrate to control (e.g., in real-time) a rate at which the thin film of material is deposited onto the substrate. For instance, the disclosed techniques for dynamically tuning the substrate support during processing of the substrate minimize (or at least reduce) variations in the thickness of the thin film of material deposited onto the substrate compared to the above-mentioned undesirable variations (e.g., greater than 10 percent) in the thickness of the thin film of material deposited onto substrates processed by conventional plasma processing systems (e.g. plasma processing systems that lack the ability to dynamically tune the substrate support during processing of the substrates). As will be described in FIG. 2 in more detail, the disclosed techniques include using tuner circuits (e.g., including an inductor and a variable capacitor arranged in series configuration or a parallel configuration) to dynamically alter (e.g., shorten, lengthen, eliminate) a ground path (e.g., between the substrate support and ground) for RF currents. For example, a capacitance of the variable capacitor may be adjusted (e.g., increased or decreased) to dynamically alter the ground path for RF currents during processing of the substrate. In this manner, the disclosed techniques allow variations in the thickness of the thin film being deposited onto the substrate to stay below a threshold variation (e.g., below at least 10 percent below at least 5 percent, below at least 1 percent).

The present disclosure may be utilized for processing substrates of any size or shape. However, the present disclosure provides particular advantage in substrates having a plan surface area of about 15,600 cm² and including substrates having a plan surface area of about a 90,000 cm² surface area (or greater). The increased size of the substrate surface area presents challenges in uniform processing due to the fixed ground path. Embodiments described herein provide a solution to these challenges during processing of the larger substrate sizes.

### Example Plasma Processing System

FIG. 1 depicts a cross-sectional view of a plasma processing system 100 according to embodiments of the present disclosure. The plasma processing system 100 is configured to process a large area substrate 101 using plasma in forming structures and devices on the large area substrate 101 for use in the fabrication of liquid crystal displays (LCD's), flat panel displays, organic light emitting diode (OLED) devices, or photovoltaic cells for solar cell arrays. The substrate 101 may be thin sheet of metal, plastic, organic material, silicon, glass, quartz, or polymer, among others suitable materials. The plasma processing system 100 may be configured to deposit a variety of materials on the large area substrates 101, including but not limited to dielectric materials (e.g., SiO₂, SiOₓN_{y}, derivatives thereof or combinations thereof), semiconductive materials (e.g., Si and dopants thereof), or barrier materials (e.g., SiNₓ, SiOₓN_{y} or derivatives thereof). Specific examples of dielectric materials and semiconductive materials that are formed or deposited by the plasma processing system 100 onto the large area substrates may include epitaxial silicon, polycrystalline silicon, amorphous silicon, microcrystalline silicon, silicon germanium, germanium, silicon dioxide, silicon oxynitride, silicon nitride, dopants thereof (e.g., B, P, or As), derivatives thereof or combinations thereof. The plasma processing system 100 is also configured to receive gases such as argon, hydrogen, nitrogen, helium, or combinations thereof, for use as a purge gas or a carrier gas (e.g., Ar, H₂, N₂, He, derivatives thereof, or combinations thereof). One example of depositing silicon thin films on the large area substrate 101 using the plasma processing system 100 may be accomplished by using silane as a processing gas in a hydrogen carrier gas.

The plasma processing system 100 generally includes a chamber body 102 having a chamber bottom wall 117a and chamber sidewalls 117b that at least partially defines a processing volume 111. A substrate support 104 is disposed in the processing volume 111. The substrate support 104 is adapted to support the substrate 101 on a top surface during processing. In some examples, the substrate support 104 may be a susceptor configured for temperatures ranging from about 80 degrees Celsius to about 400 degrees Celsius. The substrate support 104 is coupled to an actuator 138 adapted to move the substrate support at least vertically to facilitate transfer of the substrate 101 and/or adjust a distance D between the substrate 101 and a showerhead assembly 103. One or more lift pins 110a-110d may extend through the substrate support 104. The lift pins 110a-110d are adapted to contact the chamber bottom wall 117a of the chamber body 102 and support the substrate 101 when the substrate support 104 is lowered by the actuator 138 in order to facilitate transfer of the substrate 101. In a processing position as shown in FIG. 1, the lift pins 110a-110d are adapted to be flush with or slightly below the upper surface of the substrate support 104 to allow the substrate 101 to lie flat on the substrate support 104.

The substrate 101 and/or the substrate support 104 may have a surface area greater than about 5 square meters, such as about 5.5 square meters, or greater. In some embodiments, the substrate 101 and/or the substrate support 104 may include dimensions of about 2200 mm (on a minor side) by about 2500 mm (on a major side), or greater. The structures formed on the substrate 101 may be OLED devices, thin film transistors or p-n junctions to form diodes for photovoltaic cells.

The showerhead assembly 103 is configured to supply a processing gas to the processing volume 111 from a processing gas source 122. The plasma processing system 100 also comprises an exhaust system 118 configured to apply negative pressure to the processing volume 111. The showerhead assembly 103 is generally disposed opposing the substrate support 104 in a substantially parallel relationship.

In one embodiment, the showerhead assembly 103 comprises a gas distribution plate 114 and a backing plate 116. The backing plate 116 may function as a blocker plate to enable formation of a gas volume 131 between the gas distribution plate 114 and the backing plate 116. The processing gas source 122 is connected to the gas distribution plate 114 by a conduit 134. In one embodiment, a remote plasma source 107 is coupled to the conduit 134 for supplying a plasma of activated gas through the gas distribution plate 114 to the processing volume 111. The plasma from the remote plasma source 107 may include activated gases for cleaning chamber components disposed in the processing volume 111.

The gas distribution plate 114, the backing plate 116, and the conduit 134 are generally formed from electrically conductive materials and are in electrical communication with one another. The chamber body 102 is also formed from an electrically conductive material. The chamber body 102 is generally electrically insulated from the showerhead assembly 103. In one embodiment, the showerhead assembly 103 is mounted on the chamber body 102 by an insulator 135.

In one embodiment, the substrate support 104 is also electrically conductive, and the substrate support 104 and the showerhead assembly 103 are configured to be opposing electrodes for generating a plasma 108a of processing gases therebetween during processing and/or a pre-treatment or post-treatment process.

A radio frequency (RF) power source 105 is generally used to generate the plasma 108a between the showerhead assembly 103 and the substrate support 104 before, during and after processing, and may also be used to maintain energized species or further excite cleaning gases supplied from the remote plasma source 107. In one embodiment, the RF power source 105 is coupled to the showerhead assembly 103 by a first connection 106a of an impedance matching circuit 121. A second connection 106b of the impedance matching circuit 121 is electrically connected to the chamber body 102.

In one embodiment, the plasma processing system 100 includes a plurality of first RF grounding straps 109a and a plurality of second RF grounding straps 109b. Each of the first RF grounding straps 109a and second RF grounding straps 109b are coupled between the substrate support 104 and a grounded component of the chamber body 102. In one embodiment, the plurality of first RF grounding straps 109a and the plurality of second RF grounding straps 109b are configured to control the return path for returning RF current during processing of the substrate 101.

Each of the first RF grounding straps 109a may be referred to as side grounding strap 112. Each of the side grounding straps 112 are configured to selectively contact and/or provide a ground path between a side of the substrate support 104 and the chamber sidewall 117b. Additionally, each of the second RF grounding straps 109b may be referred to as bottom grounding straps 113. Each of the bottom grounding straps 113 are configured to provide a return path between the substrate support 104 and the chamber bottom 117a. In some embodiments, each of the side grounding straps 112 and the bottom grounding straps 113 are coupled to an extended member 119 electrically coupled to the substrate support 104. The extended member 119 may be a separate member coupled to a perimeter of the substrate support 104, or a structure that includes a perimeter of the substrate support 104.

Each of the side grounding straps 112 include a movable conductive member 120 that is adapted to contact a ledge 124 that is electrically coupled to the chamber sidewall 117b. Each of the side grounding straps 112 may be selectively activated to be open or closed to electrical current. In the closed position, each of the side grounding straps 112 are utilized to provide a RF conductive medium between the substrate support 104 and a component of the chamber body 102 for the RF return path. In the open position (not shown), each of the side grounding straps 112 are not electrically coupled to the chamber component (i.e., a component of the chamber body 102 that is in electrical communication with the RF power source 105). In one aspect, the open/closed characteristic of each of the side grounding straps 112 may be controlled by the elevation of the substrate support 104 relative to the showerhead assembly 103 (i.e., elevation relative to the ledges 124).

One embodiment of an RF current path during substrate processing is schematically illustrated by arrows in FIG. 1. The RF current generally travels from a first lead 123a of the RF power source 105 to the first connection 106a of the impedance matching circuit 121, then travels along an outer surface of the conduit 134 to a back surface of the backing plate 116, then to a front surface of the gas distribution plate 114. From the front surface of the gas distribution plate 114, the RF current goes through plasma 108a and reaches a top surface of the substrate 101 or the substrate support 104, then through the side grounding straps 112 and/or the bottom grounding straps 113 to an inner surface 125 of the chamber body 102. From the inner surface 125, the RF current returns to a second lead 123b of the RF power source 105 from the impedance matching circuit 121.

In one embodiment, the return path of the RF current during processing may be dependent on a spacing between the substrate support 104 and the showerhead assembly 103, which is depicted as a distance D. The spacing is controlled by the elevation of the substrate support 104. In one embodiment, the distance D is between about 200 mils to about 2000 mils during processing. At this spacing (e.g., elevation of the substrate support 104), the side grounding straps 112 and the bottom grounding straps 113 may both remain electrically coupled to the RF power source 105. In this embodiment, the RF return path taken by the RF current may be based on the electrical properties and positioning of the side grounding straps 112 and the bottom grounding straps 113. The electrical properties include resistance, impedance and/or conductance of the side grounding straps 112 and the bottom grounding straps 113. For example, since the side grounding straps 112 are closer and have less impedance for the RF current returning to the second lead 123b of the RF power source 105, the RF current flows predominantly through the side grounding straps 112 while little or no RF current flows through the bottom grounding straps 113.

The side grounding straps 112 and the bottom grounding straps 113 of the plasma processing system 100 have a fixed electrical length and therefore the electrical length of the side grounding straps 112 and/or the bottom grounding straps 113 cannot be adjusted during processing of the substrate 101, specifically when a thin film of material (e.g., silicon) is being deposited onto the substrate 101, to dynamically tune the impedance of the substrate support 104 to control (e.g., in real-time) the uniformity of the thin film of material being deposited onto the substrate 101. As will now be discussed, example aspects of the present disclosure are directed to systems and methods for dynamically tuning the impedance of the substrate support 104 during processing of the substrate 101 to control the deposition rate of the thin film of material (e.g., silicon) on the substrate 101 to provide improved uniformity of processing for such substrates.

### Example System for Dynamically Tuning Impedance of Substrate Support

FIG. 2 depicts a block diagram of components of a system 200 for dynamically tuning the impedance of a substrate support included in a plasma processing system. For simplicity, the system 200 will be described in the context of dynamically tuning the impedance of the substrate support 104 of the plasma processing system 100 discussed above with reference to FIG. 1. However, the scope of the present disclosure is not limited to use of the system 200 with the plasma processing system 100 of FIG. 1 and therefore may be used to dynamically tune substrate supports used in other types of plasma processing systems.

In some embodiments, the system 200 may be disposed within an enclosure that is positioned outside the chamber body 102 of the plasma processing system 100 discussed above with reference to FIG. 1. Stated another way, the system 200 may be disposed within an enclosure that is positioned outside of the processing volume 111 of the processing chamber. In such embodiments, the chamber body 102, specifically the chamber sidewalls 117b thereof, may define one or more apertures to allow the system 200 to be coupled (e.g., via one or more conductors) to the substrate support 104.

The system 200 includes a plurality of tuner circuits 202 (only one shown for simplicity) electrically coupled between the substrate support 104 and ground 203 (e.g., separate from the chamber body 102). In some embodiments, one or more of the tuner circuits 202 may be configured to dynamically adjust (e.g, shorten, lengthen, eliminate) a ground path from the substrate support 104 to ground 203. For instance, the one or more tuner circuits 202 may dynamically adjust the ground path during processing of the substrate 101 to dynamically tune (e.g., increase or decrease) the impedance of the substrate support 104 at one or more locations thereof. In this manner, by dynamically adjusting the ground path during processing of the substrate, the impedance of the substrate support 104 may be dynamically tuned (e.g. in real-time) at the one or more locations thereof to keep variations in the thickness of the thin film of material being deposited onto the substrate 101 below a threshold variation (e.g., less than 10 percent, less than 5 percent, less than 3 percent, less than 1 percent) across the substrate 101.

In some embodiments, one or more of the tuner circuits 202 may include an inductor 204 and a capacitor 206. As used herein, the term “inductor” broadly refers to a fixed inductor or a variable inductor unless explicitly described as being one or the other through the use of such qualifiers (e.g., “fixed” or “variable”). Likewise, as used herein, the term “capacitor” broadly refers to fixed capacitor or a variable capacitor unless explicitly described as being one or the other through the use of such qualifiers (e.g., “fixed” or “variable”).

In embodiments in which the inductor 204 is a variable inductor, an inductance of the inductor 204 may be varied (e.g., increased or decreased) to dynamically adjust the ground path. For example, in some embodiments, a variable inductor may include a coil wrapped around a core (e.g., formed of ferrite) and including multiple taps along a long axis (e.g., longitudinal) of the coil. The inductance of the variable inductor may be adjusted by changing which of the taps is used to couple to the variable inductor.

In embodiments in which the capacitor 206 is a variable capacitor, a capacitance of the capacitor 206 may be adjusted (e.g., increased or decreased) to dynamically adjust the ground path. For example, when the capacitor 206 is coupled in parallel with the substrate support 104, the capacitance of the capacitor 206 may be increased to shorten the ground path or, alternatively, may be lowered to lengthen the ground path. In some embodiments, the capacitance of the capacitor 206 may be adjusted (e.g., increased) such that the ground path effectively becomes a virtual short.

In some embodiments, one or more of the tuner circuits 202 may include one or more inductors having a fixed inductance. In some embodiments, one or more of the tuner circuits 202 may include one or more capacitors having a fixed capacitance. In some embodiments, one or more of the tuner circuits 202 may include one or more inductors having a fixed inductance and one or more capacitors having a fixed capacitance.

In some embodiments, the system 200 may include one or more sensors 208 configured to obtain sensor data 210 indicative of one or more electrical characteristics (e.g., voltage, current, phase, etc.) of the radio frequency circuit of the plasma processing system 100. For example, in some embodiments, the one or more sensors 208 may include, without limitation, a radio frequency sensor that, in some embodiments, may include a voltage sensor having a first shape (e.g., ring) and a current sensor having a second shape (e.g., helix). The radio frequency sensor may facilitate real-time measurement and monitoring of both impedance and power going into the radio frequency circuitry of the plasma processing system 100 (FIG. 1).

The system 200 may include a controller 212. In some embodiments, the controller 212 may include a processor and a memory storing computer-executable instructions that, when executed by the processor, causes the processor to perform one or more operations. The controller 212 may be communicatively coupled to the one or more sensors 208. In this manner, the controller 212 may obtain the sensor data 210 collected by the one or more sensors 208. In some embodiments, the controller 212 may be configured to provide one or more control signals 214 to the tuner circuit 202 based on the sensor data 210. The control signal(s) 214 may cause the tuner circuit 202 to make one or more adjustments to dynamically tune the impedance of the substrate support 104. For example, the control signal(s) 214 may cause the tuner circuit 202 to adjust the capacitance of the capacitor 206 to dynamically alter the ground path from the substrate support 104 to the ground 203 to, as previously mentioned, dynamically tune the impedance of the substrate support 104.

### Example Configurations for Tuner Circuit

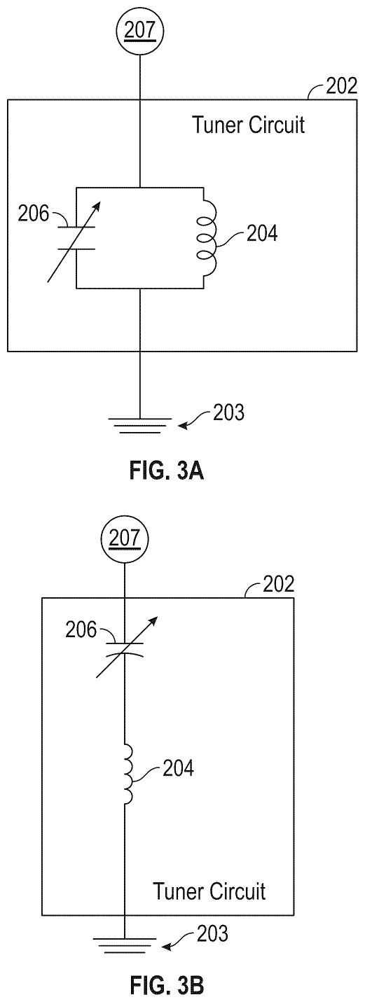

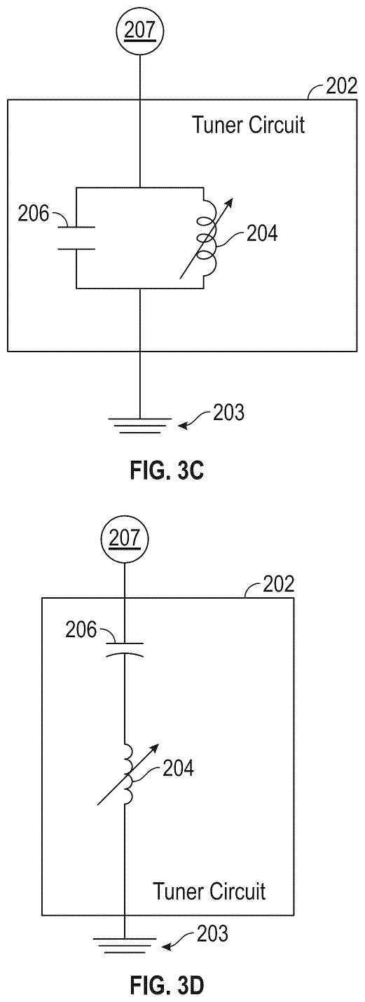

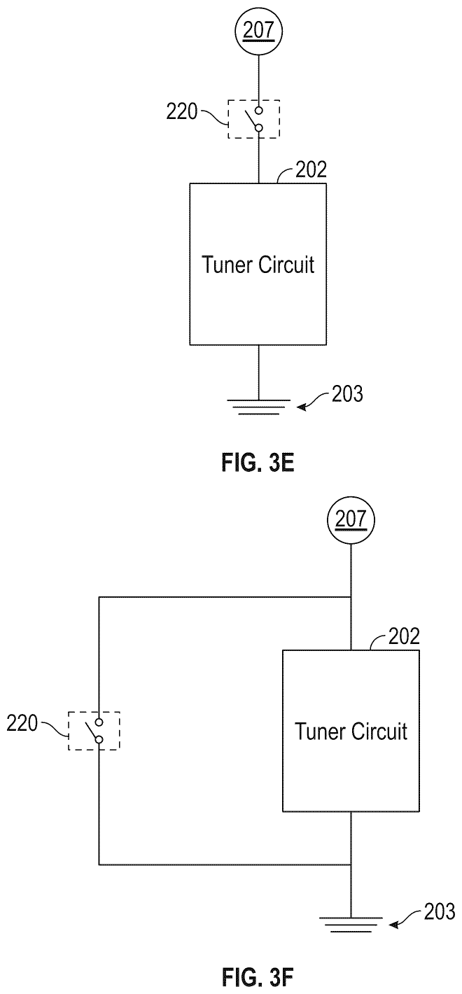

FIGS. 3A and 3B depict example configurations of a tuner circuit according to some embodiments of the present disclosure. For simplicity, the example configurations shown in FIGS. 3A and 3B will be discussed with reference to the tuner circuit 202 included in the system 200 discussed above with reference to FIG. 2.

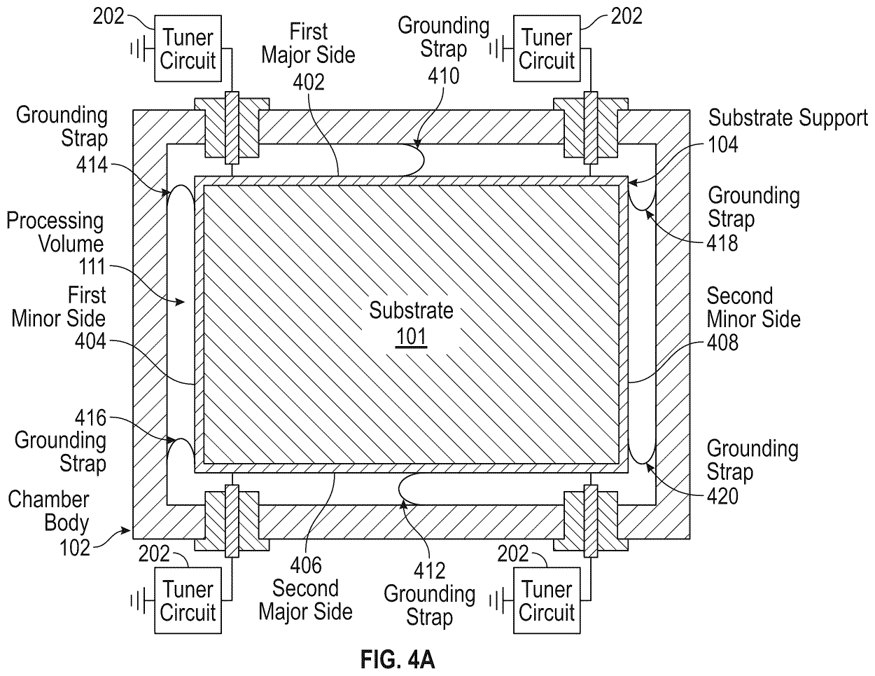

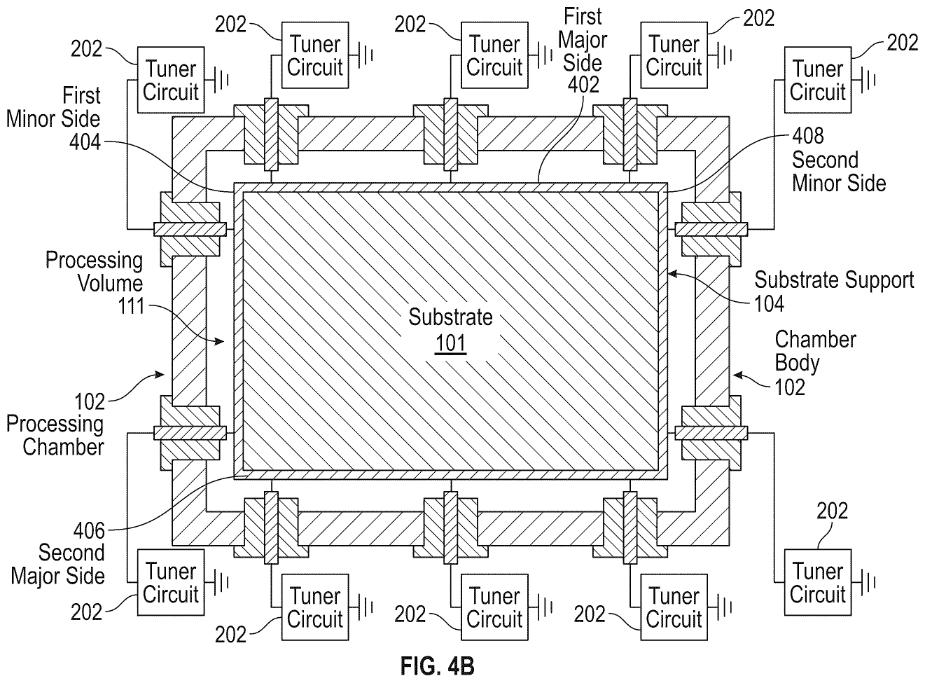

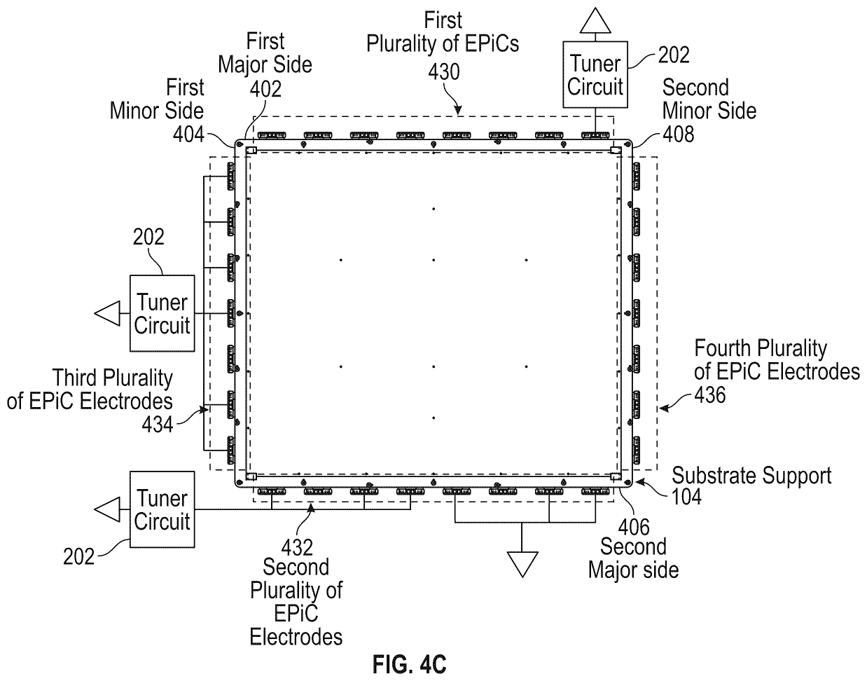

FIG. 3A depicts a first configuration of the tuner circuit 202 in which the inductor 204 and the capacitor 206 are arranged in a parallel configuration. In the parallel configuration, a high impedance or an open circuit may be achieved with respect to the ground 203 at a connection 207 for coupling the tuner circuit 202 to the substrate support 104. In fact, in the parallel configuration of the tuner circuit 202, it is possible to intentionally tune out any particular impedance resulting in neither an open circuit nor a short circuit. This intentional tuner of the impedance may be more desirable than open circuit or short circuit conditions, especially for achieving the desired deposition pattern based on contributions from one or more strategically located tuner circuits along a periphery of the substrate support 104 as illustrated below in FIGS. 4A-4C.

FIG. 3B depicts a second configuration of the tuner circuit 202 in which the inductor 204 and the capacitor 206 are arranged in a series configuration. In the series configuration, the tuner circuit 202 may exhibit zero or minimum impedance when a reactance generated by the inductor 204 and the capacitor 206 precisely cancel out at an appropriate variable capacitance value. This essentially creates a virtual ground at the connection 207 for coupling the tuner circuit 202 to the substrate support 104 (FIG. 2). In this manner, the series configuration of the tuner circuit 202 may provide effective impedance control of the substrate support 104.

FIG. 3C depicts a third configuration of the tuner circuit 202 according to some embodiments of the present disclosure. The tuner circuit 202 of FIG. 3C may differ from the tuner circuit 202 of FIG. 3A in that the inductor 204 in FIG. 3C is tunable instead of the capacitor 206 like in the tuner circuit 202 of FIG. 3A.

FIG. 3D depicts a fourth configuration of the tuner circuit 202 according to some embodiments of the present disclosure. The tuner circuit 202 of FIG. 3D may differ from the tuner circuit 202 of FIG. 3B in that the inductor 204 in FIG. 3D is tunable instead of the capacitor 206 like in the tuner circuit 202 of FIG. 3B.

FIG. 3E depicts a fifth configuration of the tuner circuit 202 according to some embodiments of the present disclosure. As shown, a switching device 220 (e.g., transistor) may be coupled between the connection 207 and the tuner circuit 202. The switching device 220 may be configured to selectively couple the tuner circuit 202 to the connection 207. For instance, in some embodiments, the switching device 220 may be configurable in a first state in which the tuner circuit 202 is decoupled from the connection 207 and a second state in which the tuner circuit 202 is coupled to the connection 207.

FIG. 3F depicts a sixth configuration of the tuner circuit 202 according to some embodiments of the present disclosure. As shown, the switching device 220 is coupled between the connection 207 and the ground 203. When the switching device 220 is in the first state, the switching device 220 completes a fixed path from the connection 207 to the ground 203 that bypasses the tuner circuit 202. Conversely, when the switching device is in the second state, the connection 207 is coupled to ground 203 via the tuner circuit 202.

### Example Configurations for Using Tuner Circuits to Dynamically Tune Impedance of a Substrate Support

FIGS. 4A, 4B, and 4C depict different configurations for dynamically tuning the impedance of the substrate support 104 according to some embodiments of the present disclosure. As illustrated, in some embodiments, the substrate support 104 may have a rectangular cross-section and may include a first major side 402, a first minor side 404, a second major side 406 opposing the first major side 402, and a second minor side 408 opposing the first minor side 404. It should be understood, however, that the scope of the present disclosure is not limited to substrate supports having a rectangular cross-section and therefore the disclosed systems and methods of the present disclosure may be used to dynamically tune substrate supports having different cross-sections.

FIG. 4A depicts a first configuration in which multiple tuner circuits 202 are used to dynamically tune the impedance of the substrate support 104 from the major sides 402, 406 thereof. For example, tuner circuits 202 may generally be positioned at opposing ends of the first major side 402 of the substrate support 104. Additionally, tuner circuits 202 may generally be positioned at opposing ends of the second major side 406 of the substrate support 104.

Furthermore, as illustrated in FIG. 4A, the first configuration may include grounding straps 410, 412 coupling a particular location (e.g., middle) of the first major side 402 and the second major side 406, respectively, to the chamber body 102. In some embodiments, the first configuration may further include grounding straps 414, 416, 418, 420 coupling particular locations (e.g., ends) along the first minor side 404 and the second minor side 408, respectively, to the chamber body 102.

FIG. 4B depicts a second configuration in which multiple tuner circuits 202 are used to dynamically tune the impedance of the substrate support 104 from each side (e.g., first major side 402, first minor side 404, second major side 406, and second minor side 408) of the substrate support 104. For example, as illustrated in FIG. 4B, three tuner circuits 202 may generally be positioned along the first major side 402 and three tuner circuits 202 may generally be positioned along the second major side 406. Additionally, two tuner circuits 202 may generally be positioned along the first minor side 404 and two tuner circuits 202 may be positioned along the second minor side 408. In some embodiments, the two tuner circuits 202 positioned along the first minor side 404 may replace the grounding straps 414, 416 discussed above with reference to FIG. 4A. Likewise, the two tuner circuits positioned along the second minor side 408 may replace the grounding straps 418, 420 discussed above with reference to FIG. 4A.

It should be understood that the additional tuner circuits 202 depicted in FIG. 4B may provide more precise control over the impedance of the substrate support 104 during processing of the substrate 101 positioned thereon. In this manner, the second configuration may provide greater control over the deposition rate of the thin film material (e.g., silicon) being deposited onto the substrate 101.

FIG. 4C depicts a third configuration in which a plurality of electrostatic plasma interface circuit (EPIC) electrodes are coupled to the substrate support 104. For example, a first plurality of EpiC electrodes 430 may be coupled to the first major side 402 of the substrate support 104 and a second plurality of EPIC electrodes 432 may be coupled to the second major side 406 of substrate support 104. Additionally, a third plurality of EPIC electrodes 434 may be coupled to the first minor side 404 of the substrate support 104 and a fourth plurality of EPIC electrodes 436 may be coupled to the second minor side 408 of the substrate support 104. Furthermore, the total number of EPIC electrodes included in the first plurality of EPIC electrodes 430 and the total number of EPIC electrodes included in the second plurality of EPIC electrodes 432 may be greater than the total number of EPIC electrodes included in the third plurality of EPIC electrodes 434 and the total number of EPiCs included in the fourth plurality of EPIC electrodes.

In some embodiments, multiple tuner circuits 202 may be coupled to the substrate support 104 to dynamically tune the substrate support 104. For example, one or more tuner circuits 202 may be coupled to each respective side of the substrate support 104. More specifically, the one or more tuner circuits 202 may be coupled to one or more EPIC electrodes included in the plurality of EPIC electrodes coupled to the respective side of the substrate support 104. For example, in some embodiments, a single tuner circuit 202 may be coupled (e.g., in parallel) to each respective EPIC electrode included in the plurality of EPIC electrodes coupled to the respective side of the substrate support 104. In this manner, the single tuner circuit 202 may dynamically control impedance of the substrate support 104 from any location along the respective side thereof.

It should be understood that the configuration depicted in FIG. 4C is intended to be illustrated of one possible configuration for dynamically tuning the substrate support 104 using tuner circuits 202 that are coupled to EPIC electrodes positioned along the perimeter of the substrate support 104. Thus, the scope of the present disclosure is intended to cover other possible configurations for dynamically tuning the impedance of the substrate support 104 using tuner circuits 202 that are coupled to the EPIC electrodes.

In each of the configurations depicted in FIGS. 4A, 4B, and 4C, the tuner circuits 202 are positioned outside of the chamber body 102. Stated another way, the tuner circuits 202 are not positioned within the processing volume 111 defined by the chamber body 102. Furthermore, the chamber body 102 may define an aperture through which a conductor extends to couple the tuner circuits 202 to the substrate support 104.

### Example Thickness Maps Illustrating Effects of Dynamic Impedance Control of Substrate Support Using Tuner Circuits

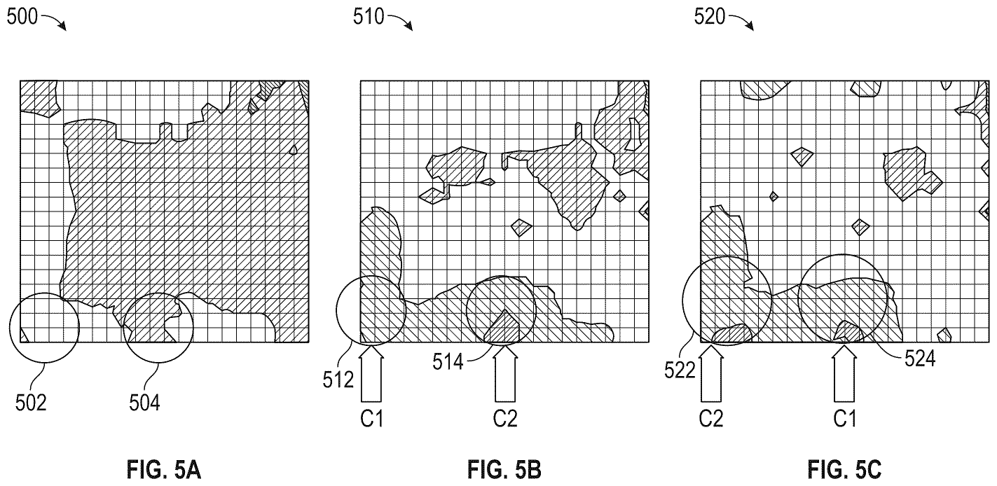

FIG. 5A depicts a two-dimensional map 500 illustrating variations in thickness of a thin film of material (e.g., silicon) deposited onto a substrate supported by a substrate support whose impedance is not dynamically tuned (e.g., by tuner circuits 202 discussed above with reference to FIG. 2) while the thin film of material is being deposited on the substrate.

FIG. 5B depicts a two-dimensional map 510 illustrating variations in thickness of the thin film of material when the substrate support is dynamically tuned using tuner circuits according to a first configuration that includes a first tuner circuit located at a first location (e.g., corner) of the substrate support and having a variable capacitor tuned to a first capacitance C1 and a second tuner circuit located at a second location (e.g., middle of a major side) of the substrate support and having a variable capacitor tuned to a second capacitance C2 that is greater than the first capacitance C1. For example, in some embodiments, the second capacitance C2 may be at least two times the first capacitance C1.

FIG. 5C depicts a two-dimensional map 520 illustrating variations in thickness of the thin film of material when the substrate support is dynamically tuned using tuner circuits according to a second configuration that is substantially the same as the first configuration discussed above in FIG. 5B except the capacitance values to which the variable capacitor in the first and second tuner circuits, respectively, are tuned are swapped. More specifically, in the second configuration, the variable capacitor included in the first tuner circuit located at the corner of the substrate support is tuned to the second capacitance C2 and the variable capacitor included in the tuner circuit located at the middle of the substrate support is tuned to the first capacitance C1 that is less than the second capacitance C2.

The two-dimensional maps 510, 520 depicted in FIGS. 5B and 5C, respectively, illustrate the improved control over the uniformity of the thickness of the thin film of material that is possible through dynamic tuning of the substrate support using tuner circuits, such as the tuner circuits 202 discussed above with reference to FIG. 2. For instance, a first region 512 of the two-dimensional map 510 in FIG. 5B and a corresponding first region 522 of the two-dimensional map 520 in FIG. 5C both have a higher deposition rate of the thin film of material compared to the corresponding first region 502 in the two-dimensional map 500 in FIG. 5A. Likewise, a second region 514 of the two-dimensional map 510 in FIG. 5B and a corresponding second region 524 of the two-dimensional map 520 in FIG. 5C both have a higher deposition rate of the thin film of material compared to the corresponding second region 504 in the two-dimensional map 500 in FIG. 5A. In both instances, the higher deposition rate is due to the use of tuner circuits at particular locations to dynamically tune the impedance of the substrate support and, in doing so, alter the deposition rate of the thin film of material being deposited on the substrate that is supported by the substrate support.

### Example Graph Illustrating a Resonance Point of the Tuner Circuit for Different Capacitances

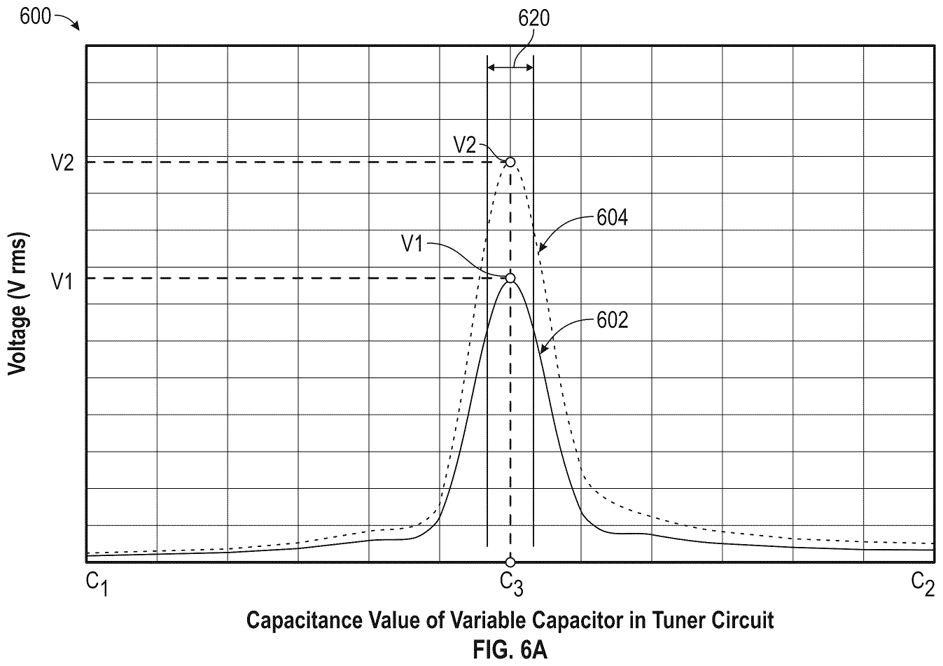

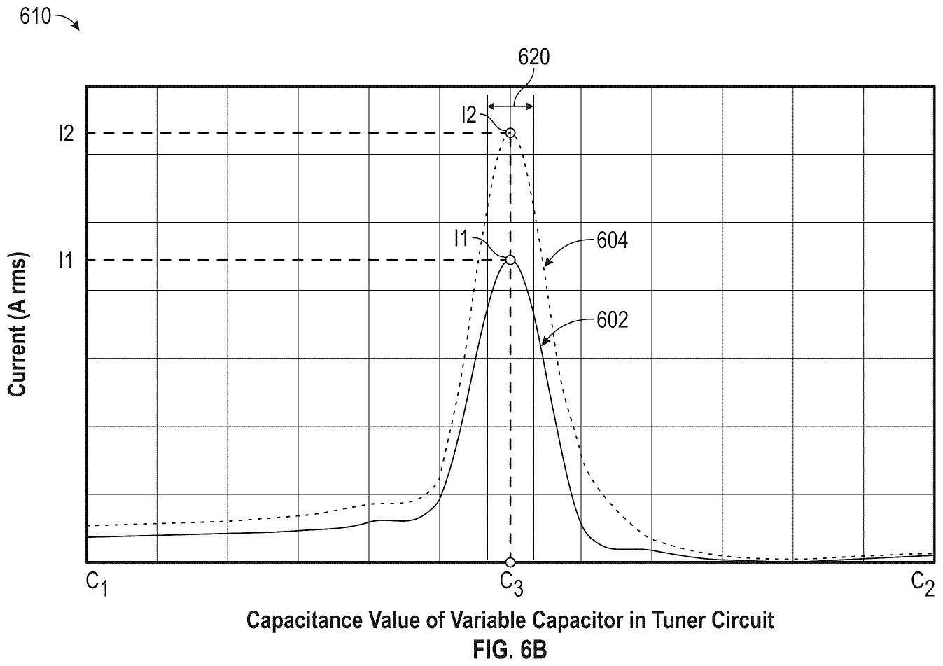

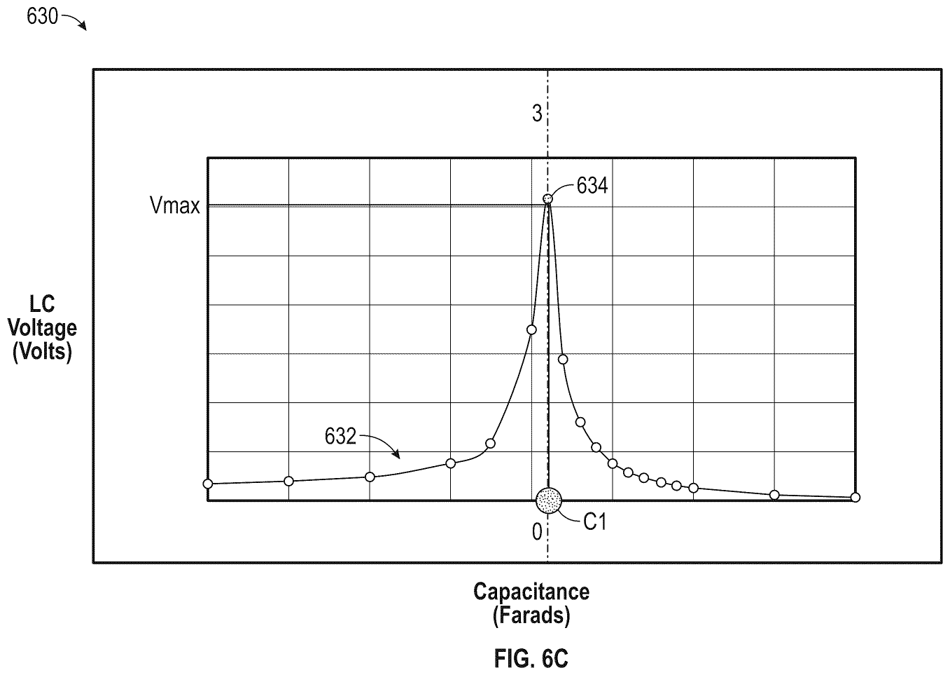

FIG. 6A is a plot 600 illustrating a resonant point of a tuner circuit (e.g., the series tuner circuit depicted in FIG. 3B) for two different power curves (e.g., first power curve 602 and second power curve 604) when a capacitance of a variable capacitor in the tuner circuit is scanned from a first capacitance C₁ to a second capacitance C₂ according to some embodiments of the present disclosure. The plot 600 illustrates that a resonance point of the tuner circuit occurs when the variable capacitor of the tuner circuit is tuned to a third capacitance C₃ that results in a peak voltage for the two different power curves.

FIG. 6B is another plot 610 illustrating the resonant point of the tuner circuit for the two different power curves when the capacitance is scanned from the first capacitance C₁ to the second capacitance C₂ according to some embodiments of the present disclosure. The only difference between plot 610 in FIG. 6B and plot 600 in FIG. 6A is the variable (e.g., voltage in FIG. 6A and current in FIG. 6B) along the y-axis. Similar to the plot 600 in FIG. 6A, the plot 610 in FIG. 6B illustrates that the resonance point of the tuner circuit occurs when the variable capacitor of the tuner circuit is tuned to the third capacitance C₃ that results in a peak current for the two different power curves.

The plots 600, 610 in FIGS. 6A and 6B, respectively, indicate that the third capacitance C₃ associated with the resonant point of the tuner circuit falls within a range of capacitance values (e.g., denoted by region 620 in FIGS. 6A and 6B) that may be associated with potential arcing due to the high resonance of the tuner circuit.

FIG. 6C depicts a plot 630 illustrating a voltage of a tuner circuit when a capacitance of a capacitor thereof is scanned according to some embodiments of the present disclosure. For instance, the vertical axis of the plot corresponds to the voltage (e.g., LC voltage) of the tuner circuit and the horizontal axis corresponds to the capacitance of the capacitor of the tuner circuit. In some embodiments, the plot 630 may be generated using the tuner circuit 202 of FIG. 3A or FIG. 3B. It should be appreciated, however, that the plot 630 may be generated using an suitable type of tuner circuit having a tunable capacitor.

The plot 630 includes curve 632 denoting the voltage of the tuner circuit as the capacitance of the capacitor thereof is varied. The curve 632 includes peak 634 corresponding to a maximum voltage of the tuner circuit. In some embodiments, the deposition rate of the thin film (e.g., Silicon Nitride) being deposited on the substrate may be controlled by adjusting the capacitance of the capacitor. For example, in some embodiments, increasing the capacitance to a value that is greater than a capacitance C1 corresponding to the peak voltage Vmax of the tuner circuit may generally increase the deposition rate of the thin film at the location (e.g. corner) of the substrate to which the tuner circuit is coupled. Alternatively, decreasing the capacitance to value that is less than the capacitance C1 corresponding to the peak voltage Vmax of the tuner circuit may generally decrease the deposition rate of the thin film at the location of the substrate to which the tuner circuit is coupled.

FIG. 6C illustrates how the tuner circuit may be used to control the deposition rate of the thin film being deposited onto the substrate. Also, although FIG. 6C is discussed in the context of adjusting the capacitance of the tuner circuit, it should be appreciated that, in alternative embodiments, the inductance of the tuner circuit may be scanned to control the deposition rate of the thin film being deposited onto the substrate. For instance, the tuner circuits of FIGS. 3C and 3D may be used in such embodiments.

### Example Connection Points on Substrate Support for Connecting Tuner Circuits

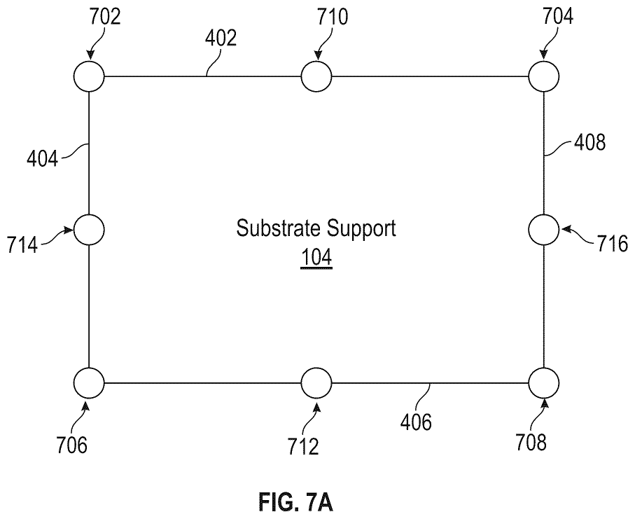

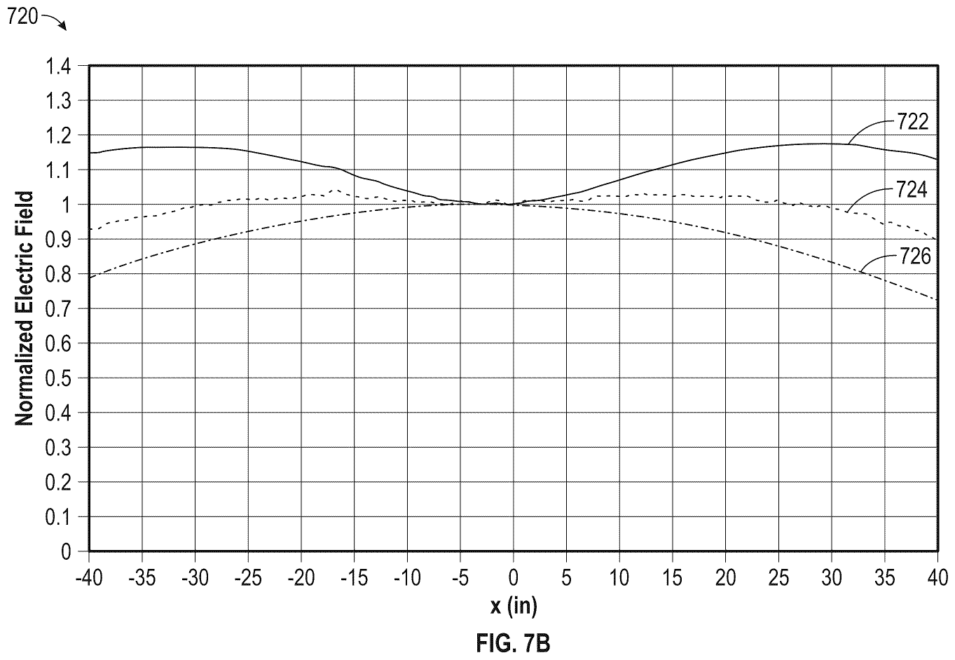

FIG. 7A illustrates different connection points for various tuner circuits to connect to a substrate support according to some embodiments of the present disclosure. For simplicity, the different connection points will be discussed with reference to the substrate support 104 discussed previously with reference to the plasma processing system 100 of FIG. 1.

As illustrated, connection points may be located at each corner of the substrate support 104. For instance, a first connection point 702 may correspond to a first corner of the substrate support 104 formed by the first major side 402 and the first minor side 404. A second connection point 704 may correspond to a second corner of the substrate support 104 formed by the first major side 402 and the second minor side 408. A third connection point 706 may correspond to a third corner of the substrate support 104 formed by the first minor side 404 and the second major side 406. A fourth connection point 708 may correspond to a fourth corner of the substrate support 104 formed by the second minor side 408 and the second major side 406.

Furthermore, additional connection points may be located at one or more intermediate locations along each side (e.g., first major side 402, first minor side 404, second major side 406, second minor side 408) of the substrate support 104. For example, a fifth connection point 710 may correspond to a middle of the first major side 406. A sixth connection point 712 may correspond to a middle of the second major side 406. A seventh connection point 714 may correspond to a middle of the first minor side 404. An eight connection point 716 may correspond to a middle of the second minor side 408.

Using the above connection points, tuner circuits may be used to control the deposition rate at various locations on the substrate. For example, in some embodiments, tuner circuits may be coupled to the corners of the substrate (e.g., via first connection point 702, second connection point 704, third connection point 706, and fourth connection point 708) to dynamically adjust the deposition rate of the thin film (e.g., silicon nitride) at the corners of the substrate. For instance, in some embodiments, the capacitance of the of the capacitor of the tuner circuits may be controlled to adjust the deposition rate of the thin film at the corners of the substrate.

In other embodiments, the tuner circuits may be connected to mid points (e.g., fifth connection point 710, sixth connection point 712, seventh connection point 714, eight connection point 716) of the different sides (e.g., first major side 402, first minor side 404, second major side 406, second minor side 408). For instance, in some embodiments, the capacitance of the capacitor of the tuner circuits may be controlled to adjust the deposition rate of the thin film at the midpoint of each side of the substrate. It should be appreciated, however, that the tuner circuits may be coupled to the sides at any suitable location thereon.

### Example Graph Illustrating Effect Tuner Impedance of Substrate Support has on Electric Field Profile of a Substrate Supported by the Substrate Support

FIG. 7B includes a plot 720 illustrating how dynamically tuning the impedance of the substrate support from different connection points thereon changes an electric field profile of the substrate according to some embodiments of the present disclosure. More specifically, the plot 720 illustrates that, by dynamically adjusting the impedance of the substrate support at different locations (e.g., the connection points discussed above with reference to FIG. 7A), the voltage of the substrate support may change such that the electric field (e.g., associated with the deposition rate of the thin film deposited onto the substrate) of the substrate may change from center low to center high.

The 720 includes an x-axis corresponding to a side (e.g., first major side 402 or second major side 406 depicted in FIG. 7A) of the substrate. The center (e.g., denoted by the number 0) of the x-axis correspond to the center of the substrate support and the far-left portion (e.g., denoted by −40) of the x-axis and the far-right portion (e.g., denoted by +40) of the x-axis correspond to opposing edges (e.g., corners) of the substrate. Furthermore, the y-axis of the plot 720 corresponds to a magnitude of the electric field of the substrate.

The plot 720 includes a first curve 722 illustrating behavior of the electric field of the substrate when a tuning circuit (e.g., tuning circuit 202 in FIG. 2) dynamically tunes the impedance of the substrate support supporting the substrate from a first connection point on the substrate support. As illustrated, the first curve 722 illustrates that the electric field is highest at the edges (e.g. at −40 on x-axis and +40 on x-axis) of the substrate and lowest at the center (e.g., denoted by 0 on x-axis) of the substrate. Thus, for the first curve 722, the deposition rate of the thin film onto the substrate would be highest at the edges of the substrate and would decrease moving inward, with the lowest deposition rate of the thin film occurring at the center of the substrate.

The plot 720 further includes a second curve 724 illustrating behavior of the electric field of the substrate when a tuning circuit dynamically tunes the substrate support from a second connection point (e.g. different from the first connection point) on the substrate support. The plot 720 also includes a third curve 726 illustrating behavior of the electric field of the substrate when a tuning circuit dynamically tunes the substrate support from a third connection point (e.g., different from the first connection point and the second connection point) on the substrate support. For both the second curve 724 and the third curve 726, the electric field is lowest at the edges of the substrate and highest at the center of the substrate.

Of the three curves shown in FIG. 7B, the electric field associated with the second curve 724 is the most uniform throughout the substrate support. Stated another way, the difference between the magnitude of the electric field at the center of the substrate support and the edges of the substrate support is smallest for the second curve 724. Thus, of the three curves, the deposition rate of the thin film onto the substrate would be most uniform by dynamically tuning the impedance of the substrate support using one or more tuning circuits to cause the substrate to have the electric field profile associated with the second curve 724.

### Example Machine Learning Based Approach for Controlling Tuner Circuits to Dynamically Tune Impedance of Substrate Support

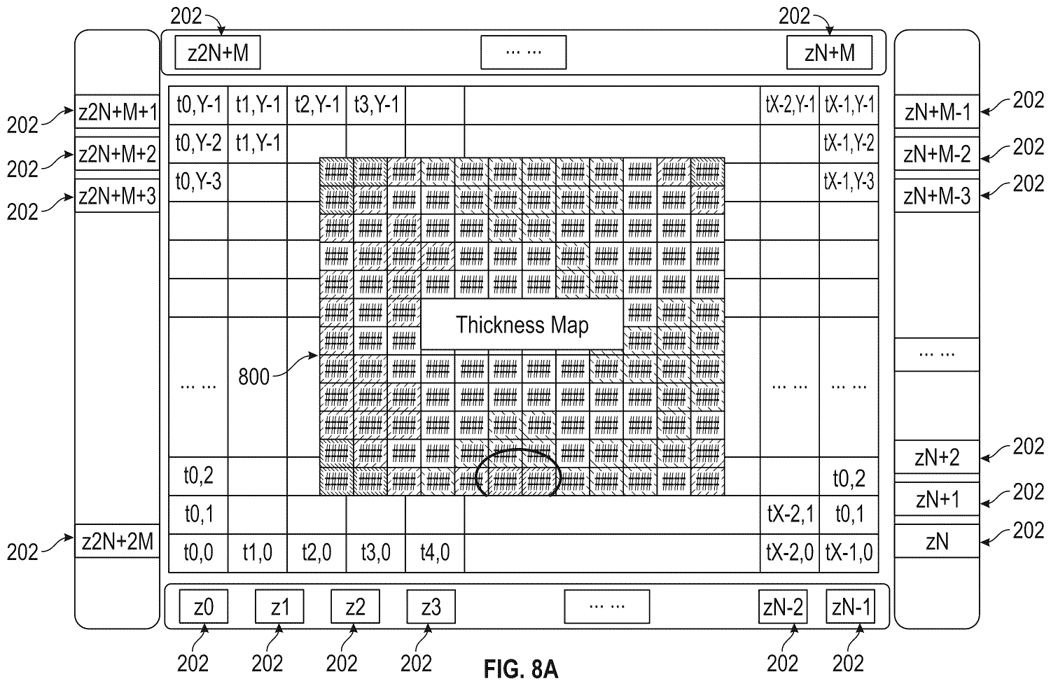

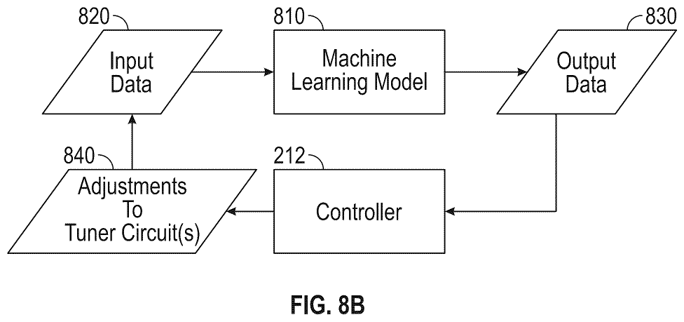

FIG. 8A and FIG. 8B depicts a machine learning based approach for controlling tuner circuits to dynamically tune the impedance of a substrate support according to some embodiments of the present disclosure. FIG. 8A depicts a deposition thickness map 800 that includes a plurality of cells, with each cell of the plurality of cells may correspond to a different location on a substrate (e.g., the substrate 101 in FIG. 1). Furthermore, the numbers included in each of the cells of the deposition thickness map 800 may indicate a thickness of the film of material at that particular location on the substrate. Although the deposition thickness map 800 includes number symbols (e.g., ####) in each of the cell, one of ordinary skill in the art would understand that the higher the number the higher the deposition rate of thin film and the lower the number the lower the deposition rate of thin film.

FIG. 8B depicts input, intermediate, and output layers of a machine learning model 810, such as a neural network or a deep neural network, that may be trained to process input data 820 comprising one or more parameters (e.g., inductance value, capacitance value) for each of the plurality of tuner circuits 202 and generate output data 830 including the deposition thickness map 800 which, as mentioned above, indicates the thickness of the thin film of material at each of the different locations on the substrate.

In some embodiments, the output data 830 generated by the machine learning model 810 may be used as feedback data to train or re-train the machine learning model 810. For example, the output data 830 (e.g., deposition thickness map 800) may indicate variations in the thickness of the thin film of material exceed a threshold variation (e.g., such as greater than 1 percent, such as greater than 3 percent, such as greater than 5 percent, etc.) at one or more locations on the substrate. Based on this, a controller (e.g., the controller 212 of the system 200 discussed above with reference to FIG. 2) may make one or more adjustments 840 to one or more parameters for one or more of the tuner circuits 202 configured to dynamically tune the impedance of the substrate support at the one or more locations. Then, the input data 820 may be updated based on the one or more adjustments 840 and may be provided again as an input to the machine learning model 810, and the machine learning model 810 may generate updated output data 830. This feedback loop to train/re-train the machine learning model 810 may be repeated until the output data 830 indicates the variation in thickness of the thin film deposited on the substrate is at or below the threshold variation.

In some embodiments, the input data 820 may include a input matrix, with each matrix element in the input matrix corresponding to a respective tuner circuit of the plurality of tuner circuits 202 and including the one or more parameters for the respective tuner circuit. Furthermore, the machine learning model 810 may be configured to multiple the input matrix with a weighting matrix. In some embodiments, each matrix element in the weighting matrix may correspond to a respective weight to be applied to a corresponding matrix element in the input matrix. Still further, in some embodiments, the output data 830 may include an output matrix, with each matrix element in the output matrix generally corresponding to the resultant of multiplying a respective matrix element in the weighting matrix with a respective matrix element in the input matrix.

In some embodiments, the weighting matrix may be updated each time the machine learning model 810 is re-trained based on updated input data. Through the process of updating individual values (e.g. weights) for the different matrix elements in the weighting matrix, the machine learning model 810 may improve (e.g., over time) the accuracy of the predictions (e.g., the output data 830) generated by the machine learning model 810.

It should be understood that the above-disclosed machine learning based approach for configuring the plurality of tuner circuits 202 to dynamically tune the impedance of the substrate support so as to minimize (or at least reduce) variations in the thickness of the of the thin film of material deposited onto the substrate may allow plasma processing systems to minimize (or at least reduce) the number of instances in which the substrate is processed having variations in the thickness of the thin film of material that exceed the threshold variation resulting in an inefficient utilization of resources associated with running the plasma processing system.

### Example Method of Configuring a Plurality of Tuner Circuits to Dynamically Tune an Impedance of a Substrate Support

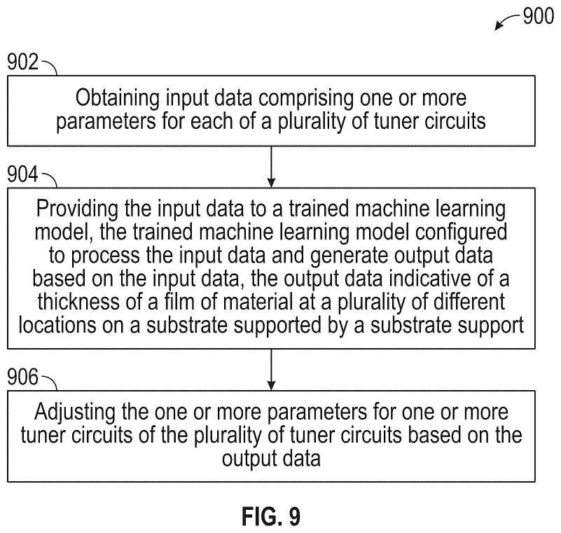

FIG. 9 is a diagram depicting an example method 900 for configuring a plurality of tuner circuits electrically coupled between an electrical ground and a substrate support supporting a substrate during a process in which a film of material is deposited onto the substrate according to some embodiments of the present disclosure. For example, the method 900 may be performed using the system 200 of FIG. 2 and the machine learning model 810 of FIG. 8B. Furthermore, although FIG. 9 depicts steps performed in a particular order for purposes of illustration and discussion, the method 900 discussed herein is not intended to be limited to any particular order or arrangement. One skilled in the art, using the disclosure provided herein, will appreciate that various steps of the method 900 can be omitted, rearranged, combined and/or adapted in various ways without deviating from the scope of the present disclosure.

At 902, the method 900 includes obtaining input data that includes one or more parameters for each of a plurality of tuner circuits (e.g., tuner circuits 202 depicted in FIGS. 2 and 8A). In some embodiments, the one or more parameters may include an inductance value for an inductor included in each of the tuner circuits and a variable capacitance value for a variable capacitor included in each of the tuner circuits. Alternatively, or additionally, the input data may, in some embodiments, be a matrix, with each matrix element in the matrix corresponding to a respective tuner circuit of the plurality of tuner circuits and including the one or more parameters for the respective tuner circuit.

At 904, the method 900 includes providing the input data to a trained machine learning model (e.g., the machine learning model 810 in FIG. 8B) configured to process the input data obtained at 902 to generate output data that is indicative of a thickness of the film at a plurality of different locations on the substrate.

At 906, the method 900 includes adjusting the one or more parameters for one or more tuner circuits of the plurality of tuner circuits based on the output data. For example, the one or more parameters of the one or more tuner circuits may be adjusted in such a way so as to minimize or reduce variations in the thickness of the thin film of material across the substrate as indicated by the output data generated by the machine learning model at 904.

Furthermore, as discussed above with reference to FIG. 8B, the method 900 may include providing updated input data that includes the adjusted one or more parameters of the one or more tuner circuits to the machine learning model as updated input data to cause the machine learning model to generate updated output data. In some embodiments, multiple iterations of this feedback loop may be implemented until the output data generated by the machine learning model indicates the variations in the thickness of the thin film of material are below a threshold variation associated with improved processing uniformity of the substrate compared to conventional plasma processing systems.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112 (f), for any limitations of any of the claims, except for those in which the claim expressly uses the words ‘means for’ together with an associated function.

The following claims are not intended to be limited to the embodiments provided but rather are to be accorded the full scope consistent with the language of the claims.

What is claimed is:

1. A process kit, comprising:
a substrate support; and
a plurality of tuner circuits electrically coupled to the substrate support and an electrical ground, each of the plurality of tuner circuits configured to adjust a ground path from the substrate support to the electrical ground during processing of a substrate supported by the substrate support to dynamically tune an impedance of the substrate support to control uniformity associated with a deposition rate of a film of material deposited onto the substrate.

2. The process kit of claim 1, wherein the substrate support includes a first major side; a second major side opposite the first major side; a first minor side extending from the first major side to the second major side; and a second minor side opposite the first minor side and extending from the first major side to the second major side.

3. The process kit of claim 2, wherein the plurality of tuner circuits include:
a first tuner circuit electrically coupled to a first corner of the substrate support formed by the first major side meeting with the first minor side;
a second tuner circuit electrically coupled to a second corner of the substrate support formed by the first major side meeting with the second minor side;
a third tuner circuit electrically coupled to a third corner of the substrate support formed by the second major side meeting with the first minor side; and
a fourth tuner circuit electrically coupled to a fourth corner of the substrate support formed by the second major side meeting with the second minor side.

4. The process kit of claim 2, wherein the plurality of tuner circuits include:
a first tuner circuit electrically coupled to the first major side of the substrate support at a point that is between a first end of the first major side and a second end of the first major side; and
a second tuner circuit electrically coupled to the second major side at a point that is between a first end of the second major side and a second end of the second major side.

5. The process kit of claim 4, wherein:
the point on the first major side of the substrate support corresponds to a middle of the first major side; and
the point on the second major side of the substrate support corresponds to a middle of the second major side.

6. The process kit of claim 4, wherein the plurality of tuner circuits further include:
a third tuner circuit electrically coupled to the first minor side of the substrate support at a point that is between a first end of the first minor side and a second end of the first minor side; and
a second tuner circuit electrically coupled to the second minor side at a point that is between a first end of the second minor side and a second end of the second minor side.

7. The process kit of claim 1, wherein each of the plurality of tuner circuits include an inductor and a capacitor.

8. The process kit of claim 7, wherein the inductor and the capacitor are arranged in a series configuration.

9. The process kit of claim 7, wherein the inductor and the capacitor are arranged in a parallel configuration.

10. The process kit of claim 7, wherein, for one or more tuner circuits of the plurality tuner circuits, the capacitor comprises a variable capacitor.

11. The process kit of claim 7, wherein, for one or more tuner circuits of the plurality of tuner circuits, the inductor comprises a variable inductor.

12. The process kit of claim 11, wherein, for the one or more tuner circuits, the capacitor comprises a variable capacitor.

13. A plasma processing system, comprising:
a processing chamber defining a processing volume;
a substrate support disposed within the processing volume; and
a plurality of tuner circuits disposed outside the processing volume, the plurality of tuner circuits electrically coupled to the substrate support and an electrical ground, the plurality of tuner circuits including one or more tuner circuits configured to adjust a ground path from the substrate support to the electrical ground during processing of a substrate supported by the substrate support to dynamically tune an impedance of the substrate support to control uniformity associated with a deposition rate of a film of material deposited onto the substrate.

14. The plasma processing system of claim 13, wherein the substrate support includes a first major side; a second major side opposite the first major side; a first minor side extending from the first major side to the second major side; and
a second minor side opposite the first minor side and extending from the first major side to the second major side.

15. The plasma processing system of claim 14, wherein the plurality of tuner circuits include:
a first tuner circuit electrically coupled to a first corner of the substrate support formed by the first major side meeting with the first minor side;
a second tuner circuit electrically coupled to a second corner of the substrate support formed by the first major side meeting with the second minor side;
a third tuner circuit electrically coupled to a third corner of the substrate support formed by the second major side meeting with the first minor side; and
a fourth tuner circuit electrically coupled to a fourth corner of the substrate support formed by the second major side meeting with the second minor side.

16. The plasma processing system of claim 14, wherein the plurality of tuner circuits include:
a first tuner circuit electrically coupled to the first major side of the substrate support at a point that is between a first end of the first major side and a second end of the first major side; and
a second tuner circuit electrically coupled to the second major side at a point that is between a first end of the second major side and a second end of the second major side.

17. The plasma processing system of claim 16, wherein:
the point on the first major side of the substrate support corresponds to a middle of the first major side; and
the point on the second major side of the substrate support corresponds to a middle of the second major side.

18. The plasma processing system of claim 16, wherein the plurality of tuner circuits further include:
a third tuner circuit electrically coupled to the first minor side of the substrate support at a point that is between a first end of the first minor side and a second end of the first minor side; and
a second tuner circuit electrically coupled to the second minor side at a point that is between a first end of the second minor side and a second end of the second minor side.

19. The plasma processing system of claim 13, wherein each of the plurality of tuner circuits includes an inductor and a capacitor.

20. A method for configuring a plurality of tuner circuits electrically coupled between an electrical ground and a substrate support supporting a substrate during a process in which a film of material is deposited onto the substrate, the method comprising:
obtaining input data comprising one or more parameters for each of the plurality of tuner circuits;
providing the input data to a trained machine learning model, the trained machine learning model configured to process the input data and generate output data based on the input data, the output data indicative of a thickness of the film of material at a plurality of different locations on the substrate; and
adjusting the one or more parameters for one or more tuner circuits of the plurality of tuner circuits based on the output data.
